(19) United States
(12) Patent Application Publication
(10) Pub. No.: US 2020/0013327 A1
(43) Pub. Date: Jan. 9, 2020

(54) COLOR TRANSFORM FOR RGBG SUBPIXEL FORMAT

(71) Applicant: Samsung Display Co., Ltd., Yongin-City (KR)

(72) Inventor: Vijayaraghavan Thirumalai, Fremont, CA (US)

(21) Appl. No.: 16/179,816

(22) Filed: Nov. 2, 2018

Related U.S. Application Data
(60) Provisional application No. 62/695,578, filed on Jul. 9, 2018.

(51) Int. Cl. G09G 3/20; G09G 3/36; H01L 27/32

(52) U.S. Cl. CPC G09G 3/2003; G09G 3/364; H01L 27/3213; G09G 2340/06; G09G 2300/0452; G09G 2340/0457; H01L 27/3218

(57) ABSTRACT

A method for directly converting Y₀Y₁CoCg or Y₀Y₁C_{b}Cᵣ image data to RGBG image data is presented, along with a display device that includes a decoder configured to perform such conversion. The conversions may be performed as follows:

$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} ) and \\ ( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Co \\ Cg\end{matrix} )$$

Wherein α is a scaling factor.

### CROSS-REFERENCE TO RELATED APPLICATION(S)

This application claims the benefit of U.S. Provisional Patent Application No. 62/695,578 filed on Jul. 9, 2018, the content of which is incorporated by reference herein.

### BACKGROUND

The inventive concept disclosed herein relates to a method and apparatus for achieving color transform in RGBG format.

Display devices such as liquid crystal displays (LCDs) and organic light-emitting diode displays (OLEDs) have various applications and come in a wide range of sizes. Most of the display devices incorporate pixels for displaying images, wherein a typical pixel includes a red (R) sub-pixel unit, a green (G) sub-pixel unit, and a blue (B) sub-pixel unit. The sub-pixels may be arranged in a number of different ways. One common layout is the RGB layout that includes the same number of R, G, and B sub-pixels repeating themselves in a systematic way, as shown in FIG. 1. Another layout, which is sometimes referred to as the “Pentile RGBG,” is the RGBG layout that includes twice as many G sub-pixels than R sub-pixels or B sub-pixels, shown in FIG. 2. As the human visual system is more sensitive to green than to red or blue, the RGBG layout is sometimes preferred.

In the RGB layout, six sub-pixels (RGBRGB) are used for two pixels of information, as shown in FIG. 3A. In contrast, in the RGBG layout, only four sub-pixels (RGBG) are used for two pixels of information (see FIG. 3B). As the RGBG layout requires ⅓ fewer pixels than RGB layout to display the same image, RGBG may have the advantage of improved power efficiency over the traditional RGB configuration.

There are different ways to lay out the sub-pixels even in the RGBG category. For example, as illustrated in FIG. 4A and FIG. 4B, the red and blue sub-pixels may be interleaved in the vertical direction or not interleaved in the vertical direction.

A display device receives source image data for R, G, and B. The source image data indicates the image that is to be rendered on a display panel. A sub-pixel rendering unit, which is part of the display device, renders the image indicated by the source image data onto the display panel. The rendering process often includes color transform or color space conversion, which refers to the transformation of an image from one color space to another color space. During color transform, color components (R, G, and B) are correlated between the image data and the sub-pixel layout of the particular device, for example for efficient compression.

For an RGB layout, popular color transforms include YCbCr and YCoCg, wherein Y=luma,

Cb=chroma blue,

Cr=chroma red,

Co=chroma orange, and

Cg=chroma green.

YCoCg color transform, shown below, is generally computationally simpler than YCbCr transform (YCbCr requires floating point calculation):

$$( \begin{matrix}Y \\ Cg \\ Co\end{matrix} ) = ( \begin{matrix}\frac{1}{4} & \frac{1}{2} & \frac{1}{4} \\ - \frac{1}{4} & \frac{1}{2} & - \frac{1}{4} \\ \frac{1}{2} & 0 & - \frac{1}{2}\end{matrix} ) ( \begin{matrix}R \\ G \\ B\end{matrix} )$$

$$Forward transform \\ ( \begin{matrix}R \\ G \\ B\end{matrix} ) = ( \begin{matrix}1 & - 1 & 1 \\ 1 & 1 & 0 \\ 1 & - 1 & - 1\end{matrix} ) ( \begin{matrix}Y \\ Cg \\ Co\end{matrix} )$$

$$Inverse transform$$

Most known color transforms are applicable to the RGB format. Since RGBG format has advantages as described above, it is desirable to generate a color transform method that is applicable to the RGBG format.

### SUMMARY

In one aspect, the inventive concept pertains to a method of displaying an RGBG-formatted image data. The method entails receiving input image data in Y₀Y₁CₒC_{g} format, and decoding the received input image data by applying the inverse-color transform as follows: determining an R value using Y₀, Y₁, Co, and Cg; determining a G₀ value using Y₀, Y₁, and no more than one of Cg and Co; determining a B value using Y₀, Y₁, Co, and Cg; and determining a G₁ value using Y₀, Y₁, and no more than one of Cg and Co.

In another aspect, the inventive concept pertains to a method for color transform of an RGBG-formatted image data. The method involves determining a first luma value based on R, B, and one of G₀ or G₁, determining a second luma value based on R, B, and the other one of G₀ or G₁, determining a first chroma value, and determining a second chroma value.

In another aspect, the inventive concept pertains to a display device configured to perform the above methods.

### DESCRIPTION OF THE DRAWINGS

FIG. 1 depicts a conventional RGB layout that includes the same number of R, G, and B sub-pixels.

FIG. 2 depicts a conventional RGBG layout that includes twice as many G sub-pixels than R sub-pixels or B sub-pixels.

FIG. 3A depicts two pixels in a conventional RGB layout.

FIG. 3B depicts two pixels in a conventional RGBG layout.

FIG. 4A and FIG. 4B depict different configurations for RGBG layouts.

FIG. 5 depicts an example of a compression scheme with a color transform.

FIG. 6 depicts an example of a basic unit in an RGBG format.

FIGS. 7A and 7B depict other examples of RGBG format to which the above color transform may be applied.

FIG. 8 depicts a block diagram of an example of a conventional display device.

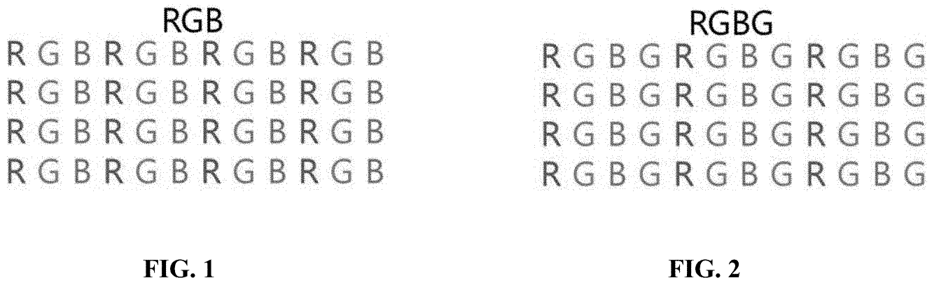

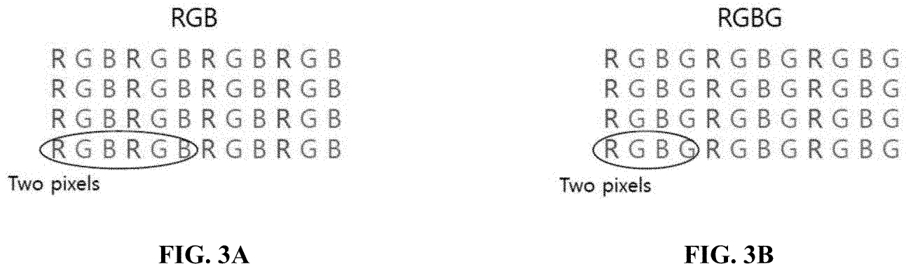

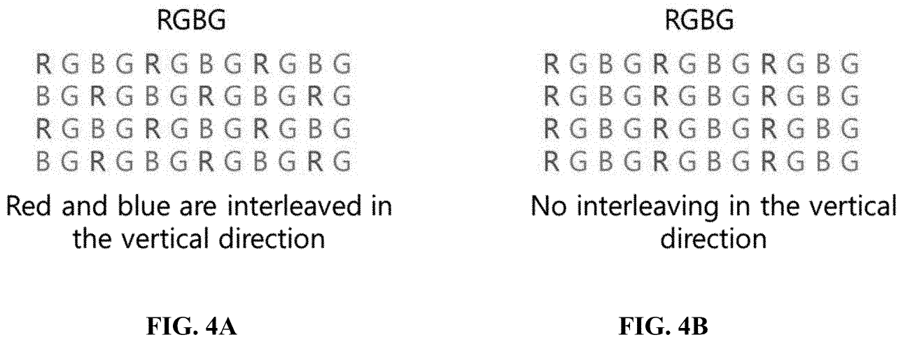

### DETAILED DESCRIPTION

A method for a color transform applicable to RGBG format is presented. More specifically, a double-luma Y₀Y₁CoCg color transform and Y₀Y₁CbCr for RGBG format is presented. The inventive concept encompasses a direct transform applicable to RGBG, which is distinguishable from a two-step transform that involves first converting RGBG to an intermediate format such as RGB format and then applying a color transform such as YCoCg or YCbCr. In a two-step transform approach, RGBG to RGB conversion may be executed by setting unknown sub-pixels to zero or calculating based on interpolation. Conversion from RGBG to RGB increases the number of pixels by ⅓, and adversely impacts compression efficiency as there are more pixels to compress in RGB than in RGBG. The two-step transform approach also involves unnecessary computation that may be costly, and has latency or delay due to the intermediate RGBG to RGB format conversion. The direct color transform for RGBG that is disclosed herein overcomes these disadvantages associated with the two-step transform approach, thereby fundamentally changing the RGBG color transform process and dramatically improving the efficiency of the color transform. Furthermore, the direct color transform for RGBG that is disclosed herein is applicable to different formats/layouts of RGBG as long as a basic unit can be formed.

The technique disclosed herein does not require an intermediate RGBG to RGB conversion. The direct Y₀Y₁CoCg color transform that is disclosed herein is easier to implement than the conventional transform because there are no floating-point calculations. As there are no division operations, the transform technique disclosed herein is hardware friendly.

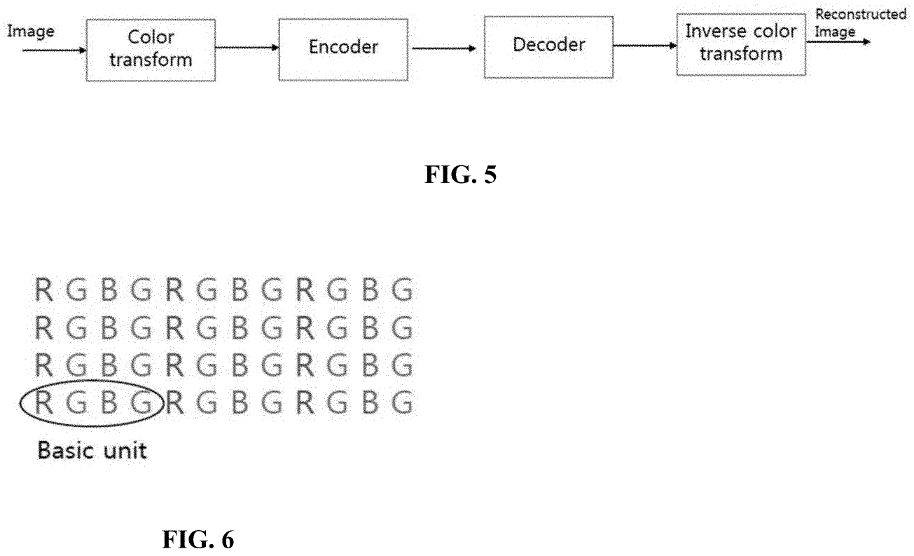

FIG. 5 depicts an example of a compression scheme with a color transform that may be executed by a display driver. As used herein, “color transform” or “color space conversion” refers to the transformation of an image from one color space to another. In the disclosure, color transform is described in the context of RGBG→Y₀Y₁CoCg conversion or RGBG→Y₀Y₁CbCr conversion as examples. In a format such as RGB or RGBG, there is a correlation between the channels R, G, and B such that there is interdependence between channels. The color transform on RGBG is applied prior to compression because compressing the RGBG itself is not optimal due to the existing correlation, and furthermore to prevent any complication of decoding process resulting from application of predictive coding where one component is predicted from another. The color transform process de-correlates the dependencies that exist between R, G, and B channels. After taking color transform, compression may be applied independently for each channel, which might simplify the decoding process.

In one embodiment, the Decoder and the Inverse color transform blocks are incorporated into a display device, which receives a color-transformed encoded input image data. The input image data may be large. If the display device is high-resolution and it is combined with high bit depth (e.g., a 4K or 8K display panel combined with bit depth of 10 or 12 bits per component), the image data would have to be fed at a high bit-rate that may be difficult to achieve due to bandwidth limitations. In such cases, compression of the data facilitates the data feed to happen at a reduced rate that further translates into minimum power consumption. The display driver configuration that is suitable for implementing the inventive concept is well known.

The color transform is performed before compression such that each component in Y₀Y₁CoCg, Y₀Y₁CbCr, YCoCg, or YCbCr is compressed independently. In the example shown in FIG. 5, color transform is performed on the RGBG input image such that the correlated components (e.g., R, G, and B) are mapped onto another space for efficient compression (via Color Transform). The color-transformed data is subjected to compression and encoded. The compressed representation of the input image data reaches a display device, and the decoding is typically performed at or near the display device that receives the encoded data. The decoded data is then inverse-color transformed back to RGBG/RGB format to generate a reconstructed image for the display device.

For an RGB layout, popular color transforms include YCbCr and YCoCg, wherein Y=luma,

Cb=chroma blue,

Cr=chroma red,

Co=chroma orange, and

Cg=chroma green.

YCoCg color transform, shown below, is generally computationally simpler than YCbCr transform:

$$( \begin{matrix}Y \\ Cg \\ Co\end{matrix} ) = ( \begin{matrix}\frac{1}{4} & \frac{1}{2} & \frac{1}{4} \\ - \frac{1}{4} & \frac{1}{2} & - \frac{1}{4} \\ \frac{1}{2} & 0 & - \frac{1}{2}\end{matrix} ) ( \begin{matrix}R \\ G \\ B\end{matrix} )$$

$$Forward transform \\ ( \begin{matrix}R \\ G \\ B\end{matrix} ) = ( \begin{matrix}1 & - 1 & 1 \\ 1 & 1 & 0 \\ 1 & - 1 & - 1\end{matrix} ) ( \begin{matrix}Y \\ Cg \\ Co\end{matrix} )$$

$$Inverse transform$$

In accordance with the inventive concept, a Y₀Y₁CoCg color transform is proposed to be applied directly to each basic unit of the RGBG format, i.e. without a conversion to the RGB format. The Y₀Y₁CoCg color transform is applied to each basic unit. A basic unit for an RGBG format contains two G, one R, and one B sub-pixels. FIG. 6 depicts an example of a basic unit in an RGBG format. Two Y luma values are calculated as there are two green sub-pixels in one basic unit.

The forward transform for RGBG is as follows:

$$( \begin{matrix}{Y}_{0} \\ {Y}_{1} \\ Co \\ Cg\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ \frac{1}{2} & 0 & - \frac{1}{2} & 0 \\ - \frac{1}{4} & \frac{1}{4} & - \frac{1}{4} & \frac{1}{4}\end{matrix} ) ( \begin{matrix}R \\ {G}_{0} \\ B \\ {G}_{1}\end{matrix} )$$

wherein α is a scaling factor or a constant, such as 1 or 2. As shown above, the first luma value Y₀ is dependent on R, G₀, and B sub-pixels. The second luma value Y₁ is dependent on R, B, and G₁. Chroma orange Co depends on R and B, and chroma green Cg depends on R, G₀, B, and G₁.

The color transform may be mathematically lossless to avoid artifacts introduced in the reconstructed image due to color transformation. This is a lossless process, and the inverse transform is as follows:

$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} )$$

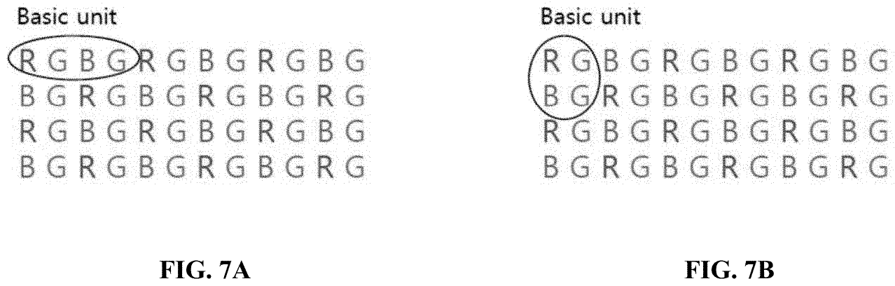

FIGS. 7A and 7B depict other examples of RGBG format to which the above color transform may be applied. As shown above, the image data (RGB in this example, but could be in RGBG or any other color space) is subjected to the color transform before getting encoded (e.g., compressed). After the decoding (e.g., de-compression) is done, the inverse color transform is applied to obtain the reconstructed image.

The double-luma Y₀Y₁CoCg color transform in accordance with the inventive concept distinguishes itself from YCoCg compression. For compressing YCoCg data, the general practice is to put more compression effort into chroma (Co, Cg) than to luma (Y), as the human vision is more sensitive to the luma than chroma On a similar note, for compressing the Y₀Y₁CoCg data, more focus may be put on the two luma channels than on the chroma channels (Co, Cg).

The techniques disclosed herein may be applied to any Reversible Color Transform (RCT), such as Y₀Y₁CbCr transform. The forward transform for Y₀Y₁CbCr is as follows:

$$( \begin{matrix}{Y}_{0} \\ {Y}_{1} \\ Cb \\ Cr\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ 0 & - \frac{1}{2} & 1 & - \frac{1}{2} \\ 1 & - \frac{1}{2} & 0 & - \frac{1}{2}\end{matrix} ) ( \begin{matrix}R \\ {G}_{0} \\ B \\ {G}_{1}\end{matrix} )$$

wherein α is a constant.

As this is a lossless process, the inverse transform is as follows:

$$( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Cb \\ Cr\end{matrix} )$$

In the Y₀Y₁CbCr transform, Y₀ depends on R, G₀, and B and Y1 depends on R, B, and G₁, similarly to the Y₀Y₁CoCg transform shown above. Cb depends on G₀, B, and G₁ but not on R, and Cr depends on R, G₀, and G₁ but not on B.

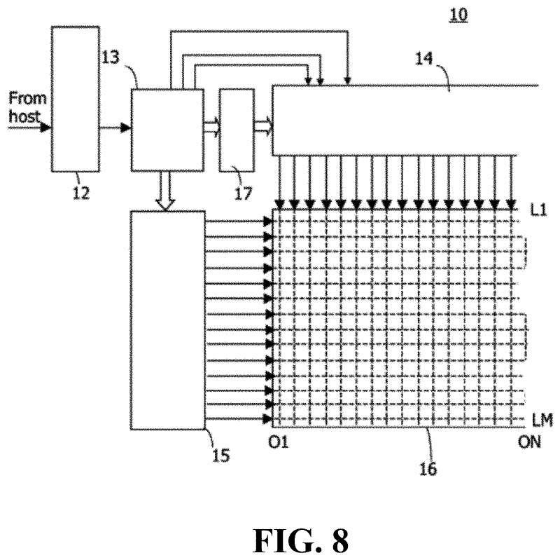

FIG. 8 depicts a block diagram of a conventional display device (e.g., TFT LCD). A plurality of column electrodes of the liquid crystal (LC) panel 16 are driven in parallel by a column driver bank 14 and a plurality of common row electrodes are driven by a row driver array 15 while being selected sequentially. An interface 12 is used as the interface between a microcontroller (not shown) and the display device 10. The interface function 12 is typically realized at the input side of a display timing controller 13. The column driver bank 14 drives the columns of the LC display and it includes N individual output buffers. The column driver bank 14 includes an array of column drivers. Typically, each column driver of the column driver bank 14 serves N column electrodes of the display panel 16 by providing analog output signals. The row driver array 15 comprises an array of row drivers. Each pixel of the display 16 is a switchable capacitor between a row and a column electrode. The display 16 may be a passive matrix LCD panel, although this is not a limitation of the inventive concept.

As illustrated in FIG. 8, there is a buffer 17 located between the display timing controller 13 and the column driver bank 14. This buffer 17 (e.g., RAM) temporality stores image data after having been compressed in accordance with the inventive concept. Image data, which represent an image to be display on the display panel 16, are given by the timing controller 13 via the buffer 17 to the column driver 14 as serial data.

The output of the buffer 17, after having been decompressed, may be sent to the column drivers inside the column driver bank 14. The data is transferred to the outputs of the column drivers in order to drive the display panel 16.

The inventive concept disclosed herein improves the efficiency of compression, which is done to represent the same image data with fewer bits. The method disclosed herein is hardware-friendly, as no floating point calculations are needed. Furthermore, by avoiding the intermediate conversion of RGBG to RGB as mentioned above, any latency or delay is reduced.

While the embodiments are described in terms of a method or technique, it should be understood that the disclosure may also cover an article of manufacture that includes a non-transitory computer readable medium on which computer-readable instructions for carrying out embodiments of the method are stored. The computer readable medium may include, for example, semiconductor, magnetic, opto-magnetic, optical, or other forms of computer readable medium for storing computer readable code. Further, the disclosure may also cover apparatuses for practicing embodiments of the inventive concept disclosed herein. Such apparatus may include circuits, dedicated and/or programmable, to carry out operations pertaining to embodiments.

Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to the embodiments.

It should be understood that the inventive concept can be practiced with modification and alteration within the spirit and scope of the disclosure. Furthermore, the inventive concept may be applied to the cases where compression is done using codecs not explicitly mentioned herein, such as DSC or VDC-M. The description is not intended to be exhaustive or to limit the inventive concept to the precise form disclosed.

What is claimed is:

1. A method of displaying an RGBG-formatted image data, comprising:
receiving input image data in Y₀Y₁CoCg format;
decoding the received input image data by applying the inverse-color transform as follows:
determining a R value using Y₀, Y₁, Co, and Cg;
determining a G₀ value using Y₀, Y₁, and no more than one of Cg and Co;
determining a B value using Y₀, Y₁, Co, and Cg; and
determining a G₁ value using Y₀, Y₁, and no more than one of Cg and Co.

2. The method of claim 1, wherein the decoding is done as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} )$$
wherein α is a scaling factor.

3. A method of displaying an RGBG-formatted image data, comprising:
receiving input image data in Y₀Y₁C_{b}Cᵣ format;
decoding the received input image data by applying the inverse-color transform as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Cb \\ Cr\end{matrix} )$$
wherein α is a scaling factor.

4. A method for color transform of an RGBG-formatted image data, comprising:
determining a first luma value based on R, B, and one of G₀ or G₁;
determining a second luma value based on R, B, and the other one of G₀ or G₁;
determining a first chroma value; and
determining a second chroma value.

5. The method of claim 4, wherein the first chroma value is a chroma orange value, further comprising determining the chroma orange value based on R and B but not G₀ or G₁.

6. The method of claim 4, wherein the second chroma value is a chroma green value, further comprising determining the chroma green value based on R, B, G₀, and G₁.

7. The method of claim 4, wherein the determining of the first luma value Y₀, the second luma value Y₁, the first chroma value Co, and the second chroma value Cg are done according to the following:
$$( \begin{matrix}{Y}_{0} \\ {Y}_{1} \\ Co \\ Cg\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ \frac{1}{2} & 0 & - \frac{1}{2} & 0 \\ - \frac{1}{4} & \frac{1}{4} & - \frac{1}{4} & \frac{1}{4}\end{matrix} ) ( \begin{matrix}R \\ {G}_{0} \\ B \\ {G}_{1}\end{matrix} )$$
wherein α is a scaling factor.

8. The method of claim 4, wherein the first luma value, the second luma value, the first chroma value, and the second chroma value are applied to one basic unit.

9. The method of claim 4, further comprising conducting an inverse transform as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} )$$
wherein α is a scaling factor.

10. The method of claim 4, wherein the first chroma value is a chroma blue value, further comprising determining the chroma blue value based on G₀, B, and G₁ but not R.

11. The method of claim 4, wherein the second chroma value is a chroma red value, further comprising determining the chroma red value based on G₀, and G₁ but not R or B.

12. The method of claim 4, wherein the determining of the first luma value Y₀, the second luma value Y₁, the first chroma value Cb, and the second chroma value Cr are done according to the following:
$$( \begin{matrix}{Y}_{0} \\ {Y}_{1} \\ Cb \\ Cr\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ 0 & - \frac{1}{2} & 1 & - \frac{1}{2} \\ 1 & - \frac{1}{2} & 0 & - \frac{1}{2}\end{matrix} ) ( \begin{matrix}R \\ {G}_{0} \\ B \\ {G}_{1}\end{matrix} )$$
wherein α is a constant.

13. The method of claim 4, further comprising achieving an inverse transform as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Cb \\ Cr\end{matrix} ) .$$

14. A display device comprising:
a memory configured to temporarily store a Y₀Y₁CₒC_{g} formatted image data that is subjected to a color transform; and
a decoder that converts the Y₀Y₁CₒC_{g} formatted image data to RG₀BG₁ formatted image data by:
determining an R value using Y₀, Y₁, Co, and Cg;
determining a G₀ value using Y₀, Y₁, and no more than one of Cg and Co;
determining a B value using Y₀, Y₁, Co, and Cg; and
determining a G₁ value using Y₀, Y₁, and no more than one of Cg and Co.

15. The display device of claim 14, wherein the decoder converts the Y₀Y₁CₒC_{g} formatted image data to RG₀BG₁ formatted image data as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} )$$
wherein α is a constant.

16. The display device of claim 14, wherein the Y₀Y₁CₒC_{g} formatted image data is encoded as follows:
$$( \begin{matrix}{Y}_{0} \\ {Y}_{1} \\ Co \\ Cg\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ \frac{1}{2} & 0 & - \frac{1}{2} & 0 \\ - \frac{1}{4} & \frac{1}{4} & - \frac{1}{4} & \frac{1}{4}\end{matrix} ) ( \begin{matrix}R \\ {G}_{0} \\ B \\ {G}_{1}\end{matrix} )$$

17. A display device comprising:
a memory configured to temporarily store a Y₀Y₁C_{b}Cᵣ formatted image data that was subjected to a color transform; and
a decoder that converts the Y₀Y₁C_{b}Cᵣ formatted image data to RG₀BG₁ formatted image data as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Cb \\ Cr\end{matrix} )$$
wherein α is a constant.

18. The display device of claim 17, wherein the Y₀Y₁CₒC_{g} formatted image data is encoded as follows:
$$( \begin{matrix}{Y}_{0} \\ {Y}_{1} \\ Cb \\ Cr\end{matrix} ) = α * ( \begin{matrix}\frac{1}{4} & \frac{1}{2} & \frac{1}{4} & 0 \\ \frac{1}{4} & 0 & \frac{1}{4} & \frac{1}{2} \\ 0 & - \frac{1}{2} & 1 & - \frac{1}{2} \\ 1 & - \frac{1}{2} & 0 & - \frac{1}{2}\end{matrix} ) ( \begin{matrix}R \\ {G}_{0} \\ B \\ {G}_{1}\end{matrix} ) .$$

19. A non-transitory computer-readable storage medium comprising instructions that, when executed, convert image data in Y₀Y₁CₒC_{g} format to image data in RG₀BG₁ format as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & 1 & - 1 \\ \frac{3}{2} & - \frac{1}{2} & 0 & 1 \\ \frac{1}{2} & \frac{1}{2} & - 1 & - 1 \\ - \frac{1}{2} & \frac{3}{2} & 0 & 1\end{matrix} ) ( \begin{matrix}{Y}_{0} \\ {Y}_{1} \\ Co \\ Cg\end{matrix} )$$
wherein α is a constant.

20. A non-transitory computer-readable storage medium comprising instructions that, when executed, convert image data in Y₀Y₁C_{b}Cᵣ format to image data in RG₀BG₁ format as follows:
$$( \begin{matrix}R \\ {G}_{0} \\ B \\ {G}_{1}\end{matrix} ) = \frac{1}{α} * ( \begin{matrix}\frac{1}{2} & \frac{1}{2} & - \frac{1}{4} & \frac{3}{4} \\ \frac{3}{2} & - \frac{1}{2} & - \frac{1}{4} & - \frac{1}{4} \\ \frac{1}{2} & \frac{1}{2} & \frac{3}{4} & - \frac{1}{4} \\ - \frac{1}{2} & \frac{3}{2} & - \frac{1}{4} & - \frac{1}{4}\end{matrix} ) ( \begin{matrix}{Y}_{0} \\ {Y}_{1} \\ Cb \\ Cr\end{matrix} )$$
wherein α is a constant.
